(19) United States
(12) Patent Application Publication
(10) Pub. No.: US 2012/0193216 A1
(43) Pub. Date: Aug. 2, 2012

(54) SUBSTRATE COOLING DEVICE, SPUTTERING APPARATUS AND METHOD FOR MANUFACTURING ELECTRONIC DEVICE

(75) Inventors: Tetsuya ENDO, Komae-shi (JP); Einstein Noel Abarra, Hachioji-shi (JP)

(73) Assignee: CANON ANELVA CORPORATION, Kawasaki-shi (JP)

(21) Appl. No.: 13/439,397

(22) Filed: Apr. 4, 2012

Related U.S. Application Data
(63) Continuation of application No. PCT/JP2010/005968, filed on Oct. 5, 2010.

(30) Foreign Application Priority Data
Oct. 5, 2009 (JP) 2009-231292

(51) Int. Cl. C23C 14/34; F25B 9/14; F25D 17/04

(52) U.S. Cl. 204/192.1; 204/298.07; 62/407; 62/6

(57) ABSTRACT

A substrate cooling device includes: a substrate holding stage including a recess defining a space between a substrate mounting unit and a substrate mounted on the substrate mounting unit; a holding member that exerts a pressing force against the substrate holding stage so as to fix the substrate to the substrate holding stage; a refrigerator connected to the substrate holding stage; a coolant gas inlet path including a coolant gas inlet opening that is provided at the substrate holding stage and opens to a recessed face of the recess, the coolant gas inlet path connecting a space in the recess via the coolant gas inlet opening to a coolant gas supply; and a coolant gas outlet path including a coolant gas outlet opening that is provided at the substrate holding stage independently of the coolant gas inlet opening and opens to the recessed face of the recess.

### RELATED APPLICATIONS

This application is a continuation of PCT/JP2010/005968, which was filed as an International Application on Oct. 5, 2010 designating the U.S., and which claims priority to Japanese Application 2009-231292 filed on Oct. 5, 2009. The entire contents of PCT/JP2010/005968 and JP2009-231292 are hereby incorporated by reference in their entireties.

### TECHNICAL FIELD

The present invention relates to substrate cooling devices to cool a substrate using a refrigerator, sputtering apparatuses and methods for manufacturing an electronic device.

### BACKGROUND ART

Conventionally a method of sputtering while keeping a substrate at a low temperature to control a crystal growth or the like is known. For instance, film formation on a substrate at a low temperature (e.g., below zero region) leads to the possibility of forming an amorphous film. This is because upon attachment to the substrate, sputtered particles lose their energy due to the low temperature substrate, thus suppressing surface migration of the particles. In order to implement a sputtering process at a low temperature, a substrate holding stage (substrate stage) has to be controlled at low temperatures.

Examples of methods to hold a substrate to a substrate stage include fixing a substrate while mechanically clamping and fixing the substrate using electrostatic chucking. Patent Literature 1 discloses a substrate holding device including an electrostatic chuck stage having a plurality of bumps for electrostatic chucking. The electrostatic chuck stage is provided with a feed opening for coolant gas to allow the coolant gas to be introduced to a rear side of a substrate sucked to the bumps. Letting coolant gas flow into between the substrate stage and the substrate is effective to cool the substrate fixed to the substrate stage efficiently. Desirable coolant gases are hydrogen and helium, and considering influences on the process, helium, which is a rare gas, is desirable. Argon gas also may be used for cooling.

### CITATION LIST

### Patent Literature

PTL1: Japanese Patent No. 3265743

### SUMMARY OF INVENTION

### Technical Problem

Many stages used for electrostatic chucking, however, are operable at a room temperature or higher, and down to −150° C. (123 K), at most, on the lower-temperature side. In the case of decreasing the substrate temperature to 50 K for instance, the substrate cannot be fixed using electrostatic chucking and has to be fixed mechanically.

For mechanical fixing, a flexible seal such as silicon rubber is typically sandwiched between the substrate and the substrate stage or a substrate fixing member, in order to seal coolant gas on the substrate rear side. However, since temperatures of 100 K or lower, for example, exceed the cold-resistance limit of most seal materials, sufficient sealing properties cannot be secured at these temperatures. As a result, there is the problem that coolant gas leaks from between an end of the substrate and the substrate stage or the substrate fixing member, and good reproducibility of the cooling state cannot be kept from substrate to substrate.

A possible method to suppress the leakage of coolant gas may be to increase a fixing force between the substrate and the substrate stage or the substrate fixing member. This increased fixing force may cause warping of a substrate, thus leading to nonuniform cooling.

In view of these problems, it is an object of the present invention to provide means capable of cooling a substrate with good reproducibility even using a refrigerator, and capable of suppressing in-plane variations in the cooling of the substrate.

### Solution to Problem

A substrate cooling device according to one aspect of the present invention includes: a vacuum vessel; a substrate holding stage provided inside the vacuum vessel and including a recess defining a space between a substrate mounting unit on which a substrate can be mounted and a substrate mounted on the substrate mounting unit; a holding member provided inside the vacuum vessel, the holding member exerting a pressing force against the substrate holding stage so as to fix the substrate to the substrate holding stage; a refrigerator provided inside the vacuum vessel, the refrigerator being fixed to the substrate holding stage at a location below the substrate holding stage that is different from that of the substrate mounting unit, and directly cooling the substrate holding stage; a coolant gas inlet path including a coolant gas inlet opening that is provided at the substrate holding stage directly cooled by the refrigerator and opens to a recessed face of the recess, the coolant gas inlet path connecting a space in the recess via the coolant gas inlet opening to a coolant gas supply; and a coolant gas outlet path including a coolant gas outlet opening that is provided at the substrate holding stage independently of the coolant gas inlet opening and opens to the recessed face of the recess, the coolant gas outlet path connecting the space in the recess via the coolant gas outlet opening to an exhaust device.

In this way, the coolant gas exhaustion opening is provided at the recess of the substrate holding stage to exhaust coolant gas, whereby reproducibility can be secured without increasing the force for fixing, and the substrate can be cooled to a target temperature while suppressing in-plane variations in the substrate temperature. Conceivably, this is because the flow of coolant gas along the recess of the substrate holding stage can suppress diffusion of the coolant gas in the substrate direction while keeping the required coolant gas pressure in the recess, resulting in suppression of gas leakage from the substrate edge to the vacuum vessel.

In a substrate cooling device according to one aspect of the present invention, the substrate holding stage includes: a base having a recess and a substrate holding face formed by a protrusion surrounding the recess, the base including a groove at a bottom face of the recess, the groove constituting the coolant gas inlet path or the coolant gas outlet path; and a sealing plate fitted to the bottom face of the recess of the base, the sealing plate including the coolant gas inlet opening or the coolant gas outlet opening communicating with the groove of the base.

In this way, the groove is formed at the base, which requires a certain strength, having a substrate holding face, and the sealing plate with a through hole formed therein is fitted to the base, whereby the substrate holding base can be made thinner while keeping the required strength for the substrate holding stage. With this configuration, the starting time until the substrate holding stage reaches the target temperature can be shortened, and thus the availability of the device can be improved.

In a substrate cooling device according to one aspect of the present invention, a wall part defining the coolant gas outlet opening includes an attachment structure that makes it possible to attach a conductance control member to an inside of the wall part, the conductance control member being for reducing an opening diameter of the coolant gas outlet opening.

With this configuration, in-plane variations can be improved by partial conductance controlling.

### Advantageous Effects of Invention

The cooling method of the present invention enables cooling of a substrate without warping of the substrate and enables reduction in in-plane cooling variations of the substrate while exerting a sufficient cooling effect.

Further features of the present invention will become apparent from the following description of exemplary embodiments with reference to the attached drawings. In the attached drawings, the same reference numerals will be assigned to the same or similar elements.

### BRIEF DESCRIPTION OF DRAWINGS

The accompanying drawings incorporated in and forming a part of the specification, illustrate embodiments of the present invention, and together with the description serve to explain the principles of the invention.

FIG. 1 illustrates an exemplary sputtering apparatus according to the present embodiment.

FIG. 2 illustrates a configuration of a substrate holding stage according to one embodiment.

FIG. 3 illustrates another configuration of a substrate holding stage according to one embodiment.

FIG. 4 is a cross-sectional view illustrating still another configuration of a substrate holding stage according to one embodiment.

FIG. 5 is a cross-sectional view illustrating a further configuration of a substrate holding stage according to one embodiment.

FIG. 6 is a cross-sectional view illustrating a still further configuration of a substrate holding stage according to one embodiment.

FIG. 7 illustrates the substrate holding stage of FIG. 6.

FIG. 8 illustrates an exemplary electronic device that is manufactured using a sputtering apparatus according to one embodiment.

FIG. 9 is a cross-sectional view illustrating a substrate holding stage of a comparative example.

FIG. 10 illustrates a sequence of each device from entry to ejection of a substrate.

### DESCRIPTION OF EMBODIMENTS

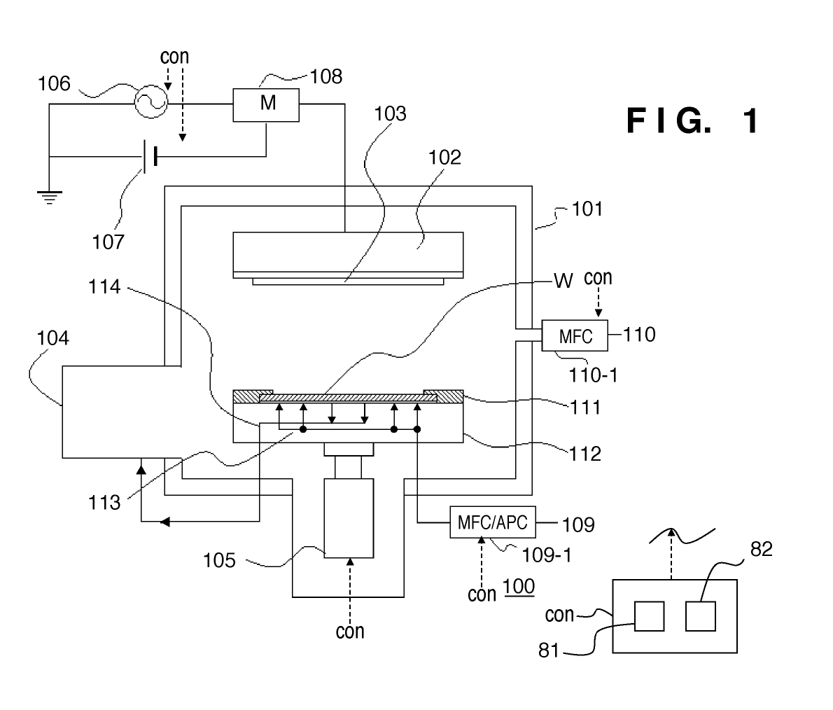

FIG. 1 illustrates an exemplary sputtering apparatus according to one embodiment of the present invention. The sputtering apparatus 100 includes, in a vacuum vessel 101, a sputtering cathode 102, a sputtering target 103 and a substrate holding stage 112.

Process gas 110 can be introduced into the vacuum vessel 101 via a flow controller (mass flow controller: MFC) 110-1. The vacuum vessel 101 is provided with an exhaust system 104 including an exhaust pump such as a turbo-molecular pump to exhaust the process gas 110 and impurity gas. The exhaust system 104 can perform exhaustion of the interior of the vacuum vessel 101 to 20 Pa or lower, for example, during film formation.

The sputtering cathode 102 is connected to a high-frequency power supply 106 and a DC power supply 107 via a matching box 108 (M). With this configuration, the sputtering cathode 102 can receive any one of electric power of high frequencies only, electric power of high frequencies+DC superimposition and electric power of DC power only. Of course, it is also possible to omit the matching box 108 and the high-frequency power supply 106, and to use only the DC power supply 107 for power supply.

The substrate holding stage 112 is provided with a substrate holding ring 111, against which a substrate W can be pressed for fixing. The substrate holding stage 112 is made of a material with high heat conductivity such as copper or copper alloy, and the substrate holding ring 111 is made of a material with heat conductivity lower than that of the substrate holding stage 112, such as iron or an iron-based alloy (e.g., stainless steel). A refrigerator 105 to cool the substrate holding stage 112 is connected below the substrate holding stage 112. The refrigerator 105 may be of a type using a stirling cycle or of a type using a GM (Gifford-McMahon) cycle, which may be selected with consideration given to the required refrigerating ability. Into the interior of the substrate holding stage 112 attached to the refrigerator 105, a coolant gas 109 can be introduced via a flow controller (mass flow controller: MFC) 109-1, and the coolant gas 109 flows through a path 113 provided in the substrate holding stage 112 and is blown to a mounting face of the substrate W. The coolant gas 109 may be in a gas form at least at a target substrate cooling temperature, and it is possible to use hydrogen or an inert gas such as helium or argon. Heat transmission by the coolant gas transmits the heat of the substrate W to the substrate holding stage 112, thus cooling the substrate W. Instead of the flow controller, an automatic gas pressure controller (auto pressure controller: APC) may be used for gas pressure control. Hereinafter, the flow controller is called “MFC/APC109-1”. After cooling the substrate W, the coolant gas 109 flows through a coolant gas outlet opening 114 and is mixed with the process gas, or is introduced to the exhaust system 104 and exhausted via an exhaust tube connecting to the exhaust system 104 of the vacuum vessel 101 without being emitted to the vacuum vessel 101. In this way, the exhaust system 104 is shared with that for the vacuum vessel 101, whereby a simple configuration at low cost can be achieved. This exhaust tube may be made of a material whose heat conductivity is smaller than that of the substrate holding stage 112, such as stainless steel, whereby the flow of heat from the vacuum vessel wall, a supporting member of piping and the like connecting to the exhaust tube to the substrate holding stage 112 can be suppressed, and cooling efficiency can be maintained.

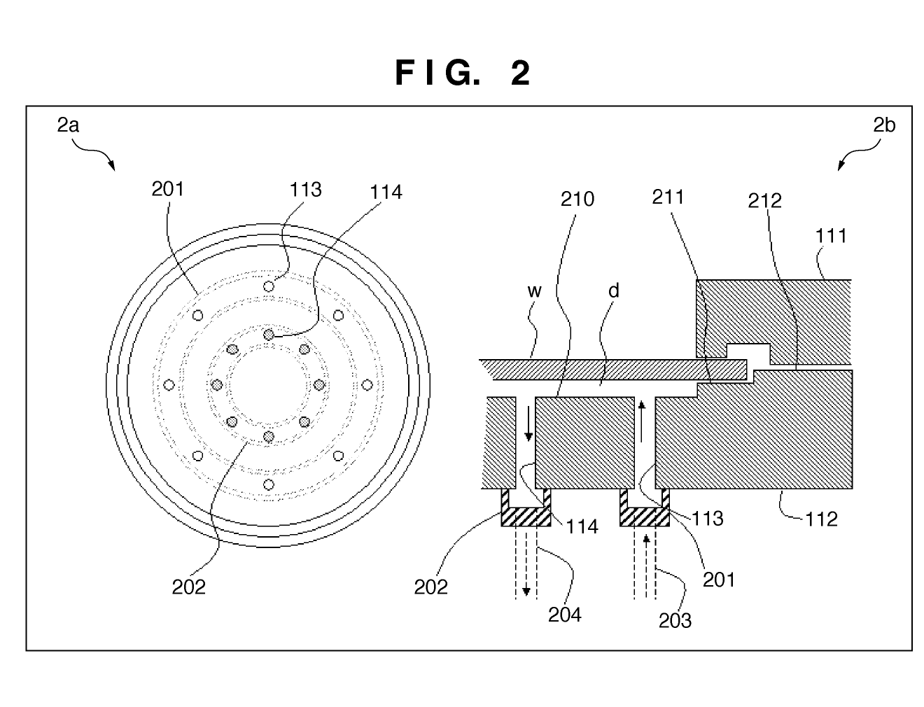

Referring next to FIG. 2, the details of the substrate holding stage 112 to which the present invention is applicable are described below. In 2a of FIG. 2, the substrate holding ring 111 and the substrate W are not shown. The substrate holding stage 112 is two-stage countersink-processed, and has a face 210, a face 211 and a face 212 increasing in level from the radially inner side to the radially outer side. The substrate holding ring 111 is provided at the face 212, and the substrate W is held between the substrate holding ring 111 and the face 211, which has an outer diameter that is larger than the substrate (2b of FIG. 2). The diameter of the face 210 is smaller than the substrate and the diameter of the face 211 is larger than the substrate, and therefore there is a gap d between the face 210 and the substrate W, defining a recess surrounded by the wall of the step between the faces 210 and 211.

The substrate holding stage 112 is provided with coolant gas inlet openings 113 and coolant gas outlet openings 114, thus allowing supply and exhaustion of coolant gas to be performed independently. The plurality of coolant gas inlet openings 113 opening to the face 210 of the substrate holding stage 112 have a common gas supply via a coolant gas inlet guide 201 provided at a bottom face of the substrate holding stage 112. The coolant gas inlet guide 201 is connected to a coolant gas inlet line 203. The coolant gas inlet guide 201 and the coolant gas inlet line 203 may be connected at one position or at a plurality of positions. Then, coolant gas introduced to the substrate W is collected to a coolant gas outlet guide 202 for the plurality of coolant gas outlet openings 114 opening to the face 210 of the substrate holding stage 112. The coolant gas outlet guide 202 is connected to a coolant gas outlet line 204 to discharge coolant gas. The coolant gas outlet guide 202 and the coolant gas outlet line 204 may be connected at one position or at a plurality of positions.

In this manner, the coolant gas inlet openings 113 and the coolant gas outlet openings 114 are scattered, whereby coolant gas can be distributed widely over the plane, and therefore local cooling due to a jet pressure can be prevented. The scattered coolant gas inlet openings 113 are led from a common inlet line of the coolant gas and the scattered coolant gas outlet openings 114 are led to a common outlet line for discharge, whereby the pressure and the flow on the rear side of the substrate W can be uniformly controlled.

### Operation of Sputtering Apparatus

FIG. 10 illustrates an exemplary operation of a sputtering apparatus of the present embodiment. The following exemplifies the operation of the sputtering apparatus of FIG. 1. The sputtering apparatus of FIG. 1 includes a process gas inlet system such as the MFC 110-1, a driving device (not illustrated) to drive the substrate holding ring 111 to a substrate holding position or to a holding release position, sputter power supplies such as the DC power supply 107 and the high-frequency power supply 106, the refrigerator 105 and a controller con to send an instruction signal to an exhaustion pump, causing it to execute a predetermined sequence. The controller con includes a storage unit 81 to store a control program and a processing unit 82 to perform operation processing for process control. The processing unit 82 may be made up of a personal computer (PC), a microcomputer or the like.

As illustrated in FIG. 10, prior to entry of a substrate to the vacuum vessel 101, the exhaustion pump and the refrigerator 105 are driven (ON) so as to keep the interior of the vacuum vessel 101 at a predetermined pressure or lower and to keep the substrate holding stage 112 at a predetermined temperature. When the substrate is conveyed into the vacuum vessel 101 (t1 of FIG. 10), then process gas is introduced to the vacuum vessel 101 (t2 of FIG. 10). Then, the substrate holding ring 111 is driven to fix the substrate at the substrate holding stage 112 (t3 of FIG. 10) and coolant gas is introduced to the rear face of the substrate (t4 of FIG. 10). After the elapse of a predetermined cooling time T1 since the introduction of the coolant gas, a sputtering power supply is turned ON (t5 of FIG. 10) to start film formation. Together with completion of the film formation processing by turning off the sputtering power supply (t6 of FIG. 10), the supply of the coolant gas and the process gas is stopped, and the fixing by the substrate holding ring 111 is released (hold release) (t6 of FIG. 10). The coolant gas is stopped (t6 of FIG. 10) and after the elapse of a stand-by time T2, the substrate is ejected (t7 of FIG. 10). During the stand-by time T2, the temperature of the substrate is brought closer to the temperatures of other members, thus preventing misalignment of the substrate when the substrate is passed to an end effector (not illustrated) of a conveyance robot that ejects the substrate from the vacuum vessel 101.

### MODIFIED EXAMPLES

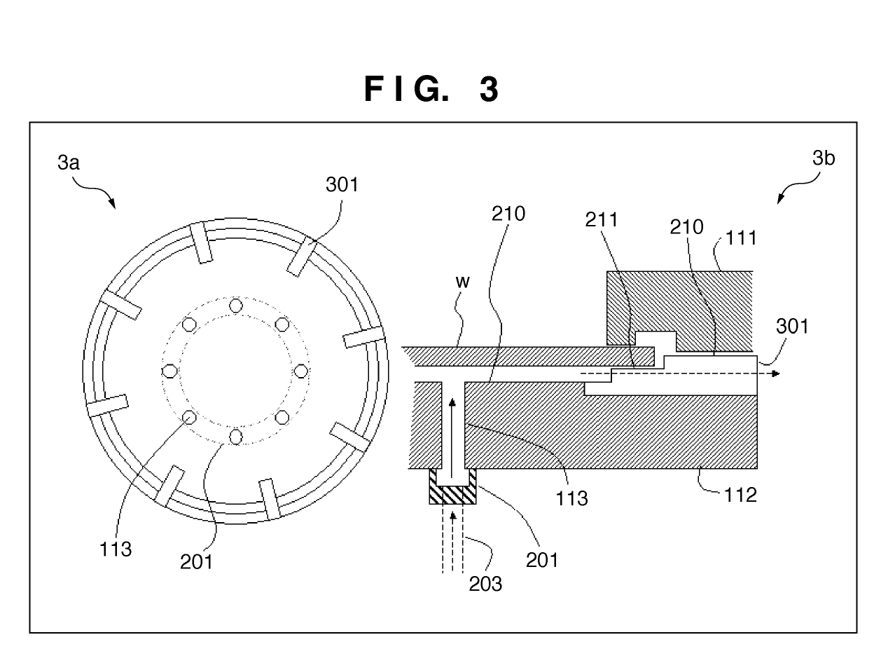

Referring further to FIG. 3, the details of another substrate holding stage 112 to which the present invention is applicable are described below. In 3a of FIG. 3, the substrate holding ring 111 and the substrate W are not shown. The substrate holding stage 112 is provided with scattered coolant gas inlet openings 113, for which a common gas supply is provided via a coolant gas inlet guide 201. The substrate holding stage 112 further includes radial grooves, forming coolant gas outlet grooves 301. In FIG. 3, the coolant gas outlet grooves 301 are formed by forming cut-outs in the faces 210 to 212, opening to the side of the substrate holding stage 112 (3b in FIG. 3). The coolant gas outlet grooves 301 may have a depth that is deeper than the face 210 or they may be at the same height as the face 210. With this configuration, coolant gas is emitted to the interior of the vacuum vessel 101, which is kept at a lower pressure than a recess of the substrate holding stage 112, from the side of the substrate holding stage 112 via the coolant gas outlet grooves 301, and is exhausted by the exhaust system 104.

The face 210 may be thermally spray treated with alumina or may be black-body-processed so as to increase its emissivity and actively use the exchange of heat by radiation. The face 211 may be processed into a specular surface so as to improve a face contact between the face 211 and the substrate W. Since a path for coolant gas exhaustion is provided, gas does not leak from the face-contact part.

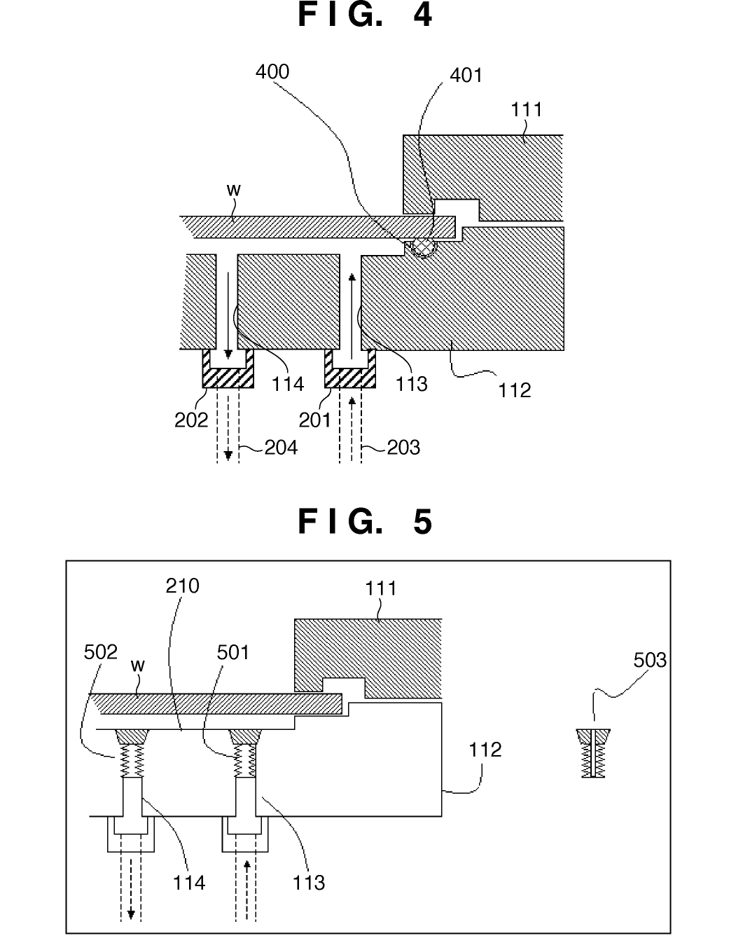

On the other hand, when there is a need to avoid scratching on the substrate W due to a contact between the substrate W and the face 211, an O-ring groove 400 and an O-ring 401 may be provided on the face 211, as illustrated in FIG. 4. The O-ring 401 is desirably made of a cold-resistant material, and is preferably made of silicon rubber. In the case of usage at a temperature lower than the cold-resistant temperature of silicon rubber, materials such as polyimide resin and polybenzimidazole (PBI resin) may be used. Note here that the O-ring 401 used herein is not a seal component to increase a gas pressure on the rear face of the substrate but for preventing scratching on the substrate. Since the present embodiment is provided with a gas outlet opening, there is no need to provide sealing.

As illustrated in FIG. 5, the coolant gas inlet openings 113 and the coolant gas outlet openings 114 that are scattered in the substrate holding stage 112 may be tap- or countersink-processed from the face 210. The countersink-processing is to prevent the head of a screw from protruding from the face 210. With this configuration, the gas pressure on the rear face of the substrate W can be controlled by sealing with the required number of screws 501 and 502. The pressure on the rear face of the substrate W can be increased for example by making the number of the coolant gas outlet openings 114 smaller than the number of the coolant gas inlet openings 113, using the screws 501 and 502 as conductance control members. Thereby, coolant gas can be spread all over the rear face of the substrate W, and thus variations in the substrate cooling temperature can be suppressed. The foregoing is an example where the number of the coolant gas outlet openings 114 and the number of the coolant gas inlet openings 113 can be easily increased/decreased without additional processing of the substrate holding stage 112, so as to increase the pressure in a range in which the substrate does not warp.

Instead of the screws 501 and 502, screws provided with a through hole parallel to the screw rotation axis, such as through-hole screws 503, may be used. If through-hole screws 503 having different through-hole diameters are provided in the coolant gas inlet openings 113 and the coolant gas outlet openings 114, then the gas pressure on the rear face of the substrate W can be controlled. For instance, if the through-hole screws provided in the coolant gas outlet openings 114 have a smaller through-hole diameter than that of the through-hole screws provided in the coolant gas inlet openings 113, then the coolant gas inlet openings 113 and the coolant gas outlet openings 114 can be made to vary in size without additional processing to the substrate holding stage 112, so that the gas pressure on the rear face of the substrate W can be controlled. Note that the screws used herein preferably have a thickness (screw diameter) of at least 4 mm, and preferably have a through-hole diameter of at least 1 mm. If screws having a thickness less than 4 mm are used, then the screws have low strength.

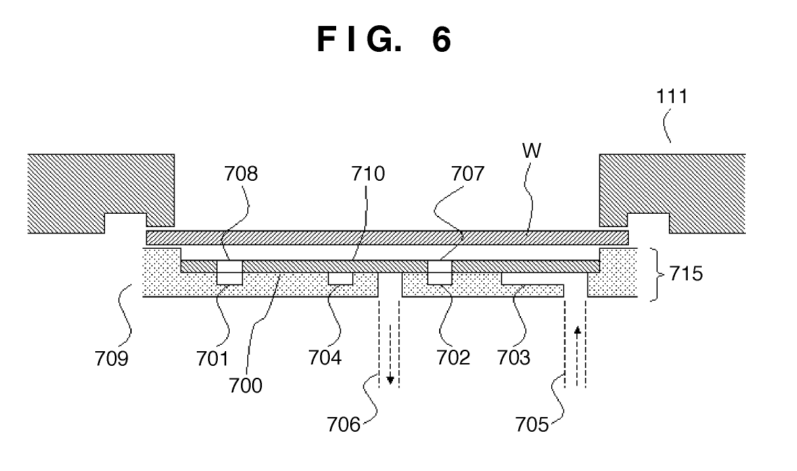

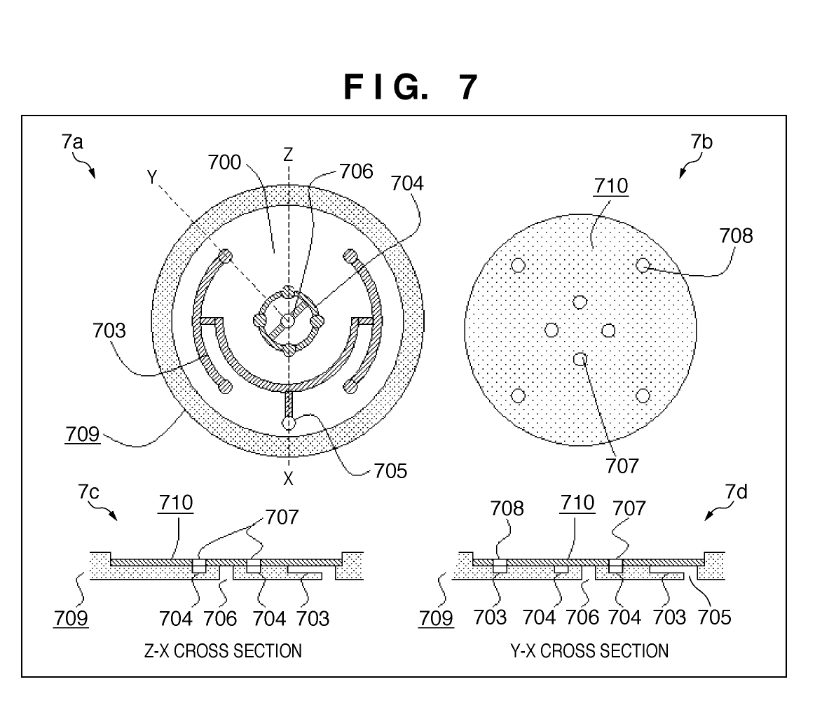

FIG. 6 and FIG. 7 illustrate an exemplary configuration of the coolant gas inlet guide 201. As illustrated in FIG. 6, a substrate holding stage 715 is made up of two separate components in a thickness direction thereof, namely a substrate holding stage base 709 and a substrate holding stage sealing plate 710. The substrate holding stage base 709 includes a recess formed by countersink-processing on its radially inner side, and is configured to be capable of holding the substrate W at a radially outer end part. At a bottom face 700 of this recess are formed a coolant gas inlet groove 703 and a base-side coolant gas inlet opening 705 enabling communication between the coolant gas inlet groove 703 and a coolant gas supply. At the bottom face 700 of this recess are further formed a coolant gas outlet groove 704 formed on the radially inner side of the coolant gas inlet groove 703 and a base-side coolant gas outlet opening 706 enabling communication between the coolant gas outlet groove 704 and the exhaust system 104 of the coolant gas. In FIG. 7, parts different in level from the bottom face 700 are illustrated with hatching or shading.

The substrate holding stage sealing plate 710 is attached to the bottom face 700 of this substrate holding stage base 709 by brazing or by screws, so that a path for gas can be formed. The substrate holding stage sealing plate 710 is provided with sealing plate-side coolant gas inlet openings 708 and sealing plate-side coolant gas outlet openings 707 penetrating therethrough, the sealing plate-side coolant gas inlet openings 708 communicating with the coolant gas inlet groove 703 and the sealing plate side coolant gas outlet openings 707 communicating with the coolant gas outlet groove 704.

In this way, the substrate holding stage 112 is formed with separate components, and grooves are formed so as to provide a branching path. This configuration makes it possible to increase the design freedom, and to configure a device having a greater cooling effect. For instance, in the example of 7a, 7b, 7c and 7d of FIG. 7, the paths from the base-side coolant gas inlet opening 705 to the respective sealing plate-side coolant gas inlet openings 708 have substantially the same length (within a range of relative difference of (difference from median/median)±5%) and the branching paths for gas inlet have substantially the same length. Similarly, the outlet grooves 704 also have substantially the same branching path length (within a range of relative difference of (difference from median/ median)±5%). This configuration can prevent nonuniform diffusion of coolant gas.

There is no limitation to setting the lengths to be the same. For instance, since the temperature of the components tends to be lower in the vicinity of a substrate entrance for conveying the substrate into the vacuum vessel 101, branching paths that open to the side that is closer to the substrate entrance may be made longer or narrower than those on the far side so as to make their conductance smaller. At such a part where a difference of cooling efficiency or the like occurs regularly, a uniform cooling effect can be achieved more easily and at lower cost by controlling branching paths than by independently controlling different gas inlet paths. Similarly, if gas inlet paths are provided on the radially outer side and on the radially inner side, the branching paths on the radially inner side may be made longer or narrower so as to decrease their conductance, thus obtaining a similar effect.

In all these application examples, the flow of coolant gas may be set to at least 3 sccm. If the flow is less than 3 sccm, the substrate cooling efficiency is degraded. A larger gas flow will hardly lead to the warping of the substrate W because the application examples of the present invention are provided with a gas outlet opening, and variations in substrate cooling temperature also can be suppressed by a larger gas flow. However, if the number and the size of the gas outlet openings can be controlled as in the example of FIG. 5, a pressure on the rear face of the substrate W may occur that causes warping of the substrate W. In that case, if the gas pressure on the rear face of the substrate W is set to 500 Pa or less, variations in the substrate cooling temperature due to warping of the substrate W can be substantially ignored.

The foregoing is a description of several embodiments, but applications of the present invention are not limited to the aforementioned embodiments. Although the coolant gas inlet openings 113 may be provided at the center only, it is preferable to provide the coolant gas inlet openings 113 in a scattered manner as stated above, because this way the coolant gas can be diffused and local cooling due to a jet pressure can be prevented.

There is no limitation to a configuration in which coolant gas is introduced from the radially outer side and exhausted from the radially inner side, and various configurations can be used. For example, the coolant gas may be introduced from the radially inner side and may be exhausted to the radially outer side, the coolant gas inlet openings 113 and the coolant gas outlet openings 114 may be provided alternately on the same circumference and the openings may be scattered not concentrically but in a lattice form. Among these configurations, the configuration as in the aforementioned embodiments of introducing coolant gas from the radially outer side and exhausting the coolant gas from the radially inner side is preferable, because this configuration makes the flow or the flow pressure larger on the radially inner side than on the radially outer side, which has a larger volume, so that the heat transmission on the radially inner side is effected by coolant gas from which heat has been already taken on the radially outer side, and so heat transmission efficiency can be made uniform between the radially inner and the outer sides.

In the above-described embodiments, all the recess have a flat bottom face, but there is no limitation to this. The bottom face may have a protrusion to guide the flow. However, with regard to gas diffusion, it is preferable if this protrusion has a height of ½ of the depth of the recess. The substrate cooling device according to the present embodiment can be applied not only to a sputtering apparatus but also to other apparatuses such as a dry etching apparatus and an ion beam etching apparatus.

### Manufacturing Method of Electronic Device

FIG. 8 illustrates an exemplary electronic device that is manufactured using a sputtering apparatus of the present invention. FIG. 8 illustrates a Magnetic Tunnel Junction (MTJ) device. These laminated films on a substrate can be manufactured by sputtering. Among them, a CoFe ferromagnetic layer sandwiching a tunnel barrier layer (containing mainly magnesium oxide) is formed by sputtering while keeping the substrate temperature at −0° C. or less, for example. The tunnel barrier layer is formed by sputtering using a ceramic target containing magnesium oxide.

Through this process, MgO oriented in a direction perpendicular to the (001) plane can be obtained by forming amorphous FeCo through film formation at a low temperature. Heat treatment of this makes it possible to form an MTJ device with a high MR ratio where FeCo is crystalized using MgO as a template. Examples

### Comparative Example 1

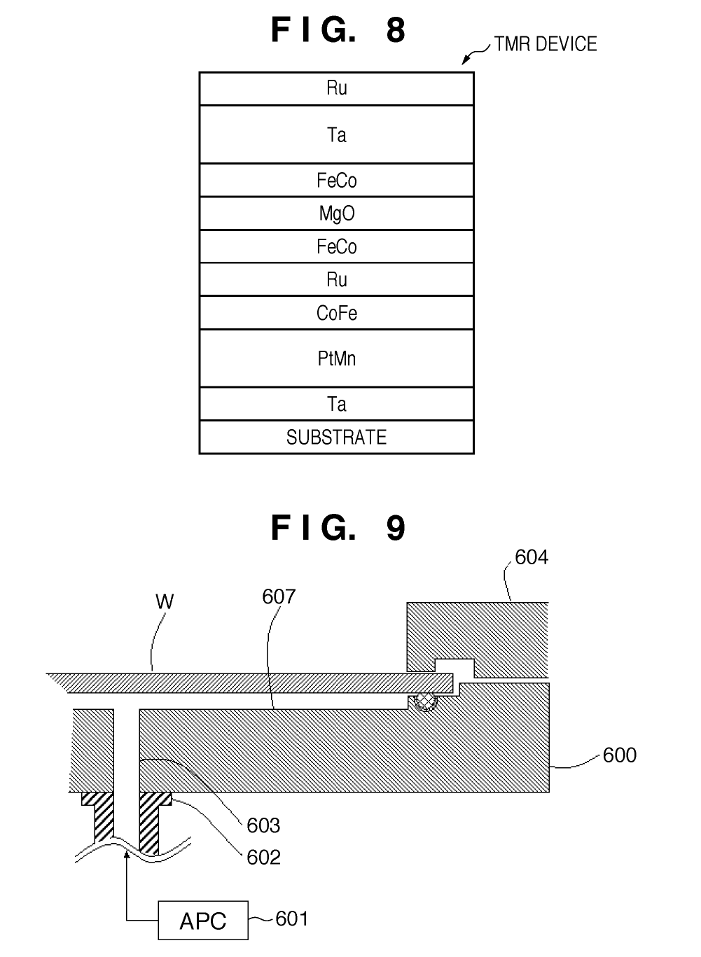

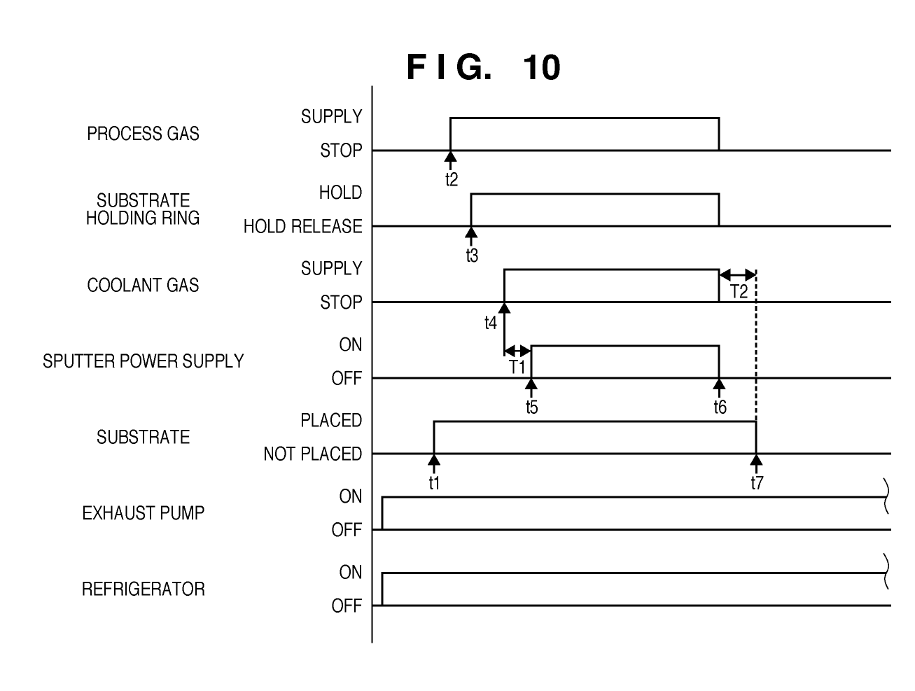

In order to clarify the effect of the present invention, comparative examples are described in the following. FIG. 9 illustrates a configuration to cool a substrate in a comparative example. At the center of a substrate holding stage 600, a coolant gas inlet opening 603 with a diameter of 5 mm is provided, and the coolant gas inlet opening 603 is connected to a coolant gas line 602 on the rear side of the substrate holding stage 600. An exhaust path to actively exhaust the coolant gas is not provided. The substrate holding stage 600 and a substrate W are hermetically sealed by a silicon rubber O-ring 606. The gas pressure of the coolant gas is controlled by an automatic gas pressure controller (APC) 601. The pressing force of a substrate pressing ring 604 was set to 147 N. The sealed gas was helium gas that was introduced at 10 Torr (1330 Pa). A gap between a face 607 and W was set to 0.2 mm.

The temperature of the substrate holding stage 600 was set to −90° C., and a Si substrate with an oxide film having a diameter of 200 mm and a thickness of 0.725 mm was used. The temperature of the substrate was measured with a thermocouple (e.g., of the K-type) attached at the center of the substrate and at a position 80 mm away from the center (referred to as “edge” below).

As a result, the temperature of the substrate in equilibrium was measured to be −65° C. at the substrate center and −80° C. at the substrate edge (Table 1). It seems that this result is due to warping (a shape where the center has moved away from the substrate holding stage) or deformation of the substrate by the pressing force for hermetically sealing the coolant gas and due to warping of the substrate by the pressure of the coolant gas.

TABLE 1

Substrate In-Plane Temperature

| | Substrate center | Substrate edge |
|---|---|---|
| | (R = 0) | (R = 80) |
| Comparative Ex. 1 | −65° C. | −80° C. |
| Comparative Ex. 2 | Not reproducible | Not reproducible |
| Example 1 | −78° C. | −80° C. |
| Example 2 | −79° C. | −77° C. |
| Example 3 | −145° C. | −149° C. |

### Comparative Example 2

When the gas pressure of the hermetically sealed coolant gas was set to 1 Torr and the substrate pressing force was weakened to 9.8 N, warping of the substrate was reduced, but the leakage amount of the gas increased, the substrate edge temperature varied with time and further varied from substrate to substrate, and reproducibility was not obtained (Table 1).

That is, as the substrate pressing force for hermetically sealing the coolant gas is increased, and also as the pressure of coolant gas is increased, the substrate warps, and thus variations occur in the substrate in-plane cooling temperature. As the substrate pressing force is decreased to reduce warping of the substrate, the coolant gas leaks, and thus reproducibility of the cooling temperature cannot be obtained.

### Example 1

A substrate cooling experiment was conducted with the configuration as illustrated in FIG. 2, to which the present invention is applicable. The substrate holding ring 111 was made of SUS, and the substrate holding stage 112 was made of copper. The face 210 was not especially surface-treated, and was left as it was cut. Eight coolant gas inlet openings 113, each an opening of 1 mm in diameter, were arranged at positions away from the center of the substrate holding stage 112 that are progressively shifted by 45 degrees. The coolant gas outlet openings 114 also had a diameter of 1 mm, and eight of the coolant gas outlet openings 114 were arranged inward with respect to the coolant gas inlet openings 113 at positions away from the center of the substrate holding stage 112 that are progressively shifted by 45 degrees.

The face 210 had a diameter of 196 mm, the face 211 had a diameter of 203 mm and the distance between the face 210 and the substrate W was 0.2 mm. A Stirling cycle type refrigerator was connected to the substrate holding stage 112, and the temperature of the substrate holding stage 112 was controlled to −90° C. The substrate pressing force was set to 19.6 N, and the gas flow was controlled to 100 sccm by a gas flow controller. The temperature of the substrate was measured with a thermocouple (e.g., of the K-type) attached at the substrate center and at a position 80 mm away from the center (referred to as “edge” below).

As a result, the temperature of the substrate was ultimately measured to be −78° C. at the substrate center and −80° C. at the substrate edge, so that the in-plane temperature difference was reduced. The differences among substrates was also reduced to within ±2° C., illustrating that the effect of the present invention (Table 1).

### Example 2

Next, a substrate cooling experiment was conducted with the configuration illustrated in FIG. 3, to which the present invention is applicable. The substrate holding ring 111 was made of SUS, and the substrate holding stage 112 was made of copper. The face 210 was not especially surface-treated, and was left as it was cut. Eight coolant gas inlet openings 113, each an opening of 1 mm in diameter, were arranged at positions away from the center of the substrate holding stage 112 that are progressively shifted by 22.5 degrees.

The face 210 had a diameter of 196 mm, the face 211 had a diameter of 203 mm and the distance between the face 210 and the substrate W was 0.2 mm. A Stirling cycle type refrigerator was connected to the substrate holding stage 112, and the temperature of the substrate holding stage 112 was controlled to −90° C. The substrate pressing force was set to 19.6 N, and the gas flow was controlled to 100 sccm by a gas flow controller. The temperature of the substrate was measured with a thermocouple (e.g., of the K-type) attached to the substrate center and a position 80 mm away from the center (referred to as ¢edge” below).

As a result, the temperature of the substrate was ultimately measured to be −79° C. at the substrate center and −77° C. at the substrate edge, so that the in-plane temperature difference was reduced. The difference among substrates was also reduced to within ±2° C., illustrating the effect of the present invention (Table 1).

### Example 3

Then, substrate cooling was confirmed with the configuration illustrated in FIG. 6, to which the present invention is applicable. The substrate holding ring 111 was made of SUS, and the substrate holding stage base 709 and the substrate holding stage sealing plate 710 were made of copper. The face of the substrate holding stage sealing plate 710 facing the substrate was not especially surface-treated, and was left as it was cut. Four coolant gas inlet openings 708, each an opening of 1 mm in diameter, were arranged at positions away from the center of the substrate holding stage 715 that are progressively shifted by 90 degrees. The coolant gas outlet openings 707 also had a diameter of 1 mm, and four of the coolant gas outlet openings 707 were arranged inward with respect to the coolant gas inlet openings at positions away from the center of the substrate holding stage 715 that are progressively shifted by 90 degrees.

The distance between the substrate holding stage sealing plate 710 and the substrate W was 0.2 mm. A not-shown GM cycle type refrigerator was connected to the substrate holding stage 715, and the temperature of the substrate holding stage 715 was controlled to −200° C. The substrate pressing force was set to 19.6 N, and the gas flow was controlled to 50 sccm by a gas flow controller. The temperature of the substrate was measured with a thermocouple (e.g., of the K-type) attached at the substrate center and a position 80 mm away from the center (referred to as “edge” below).

As a result, the temperature of the substrate in equilibrium was measured to be −145° C. at the substrate center and −149° C. at the substrate edge, so that the in-plane temperature difference was reduced. The difference among substrates was also reduced to within ±2° C., illustrating the effect of the present invention (Table 1).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-231292, filed Oct. 5, 2009, which is hereby incorporated by reference herein in its entirety.

1. A substrate cooling device, comprising:
a vacuum vessel;
a substrate holding stage provided inside the vacuum vessel and including a recess defining a space between a substrate mounting unit on which a substrate can be mounted and a substrate mounted on the substrate mounting unit;
a holding member provided inside the vacuum vessel, the holding member exerting a pressing force against the substrate holding stage so as to fix the substrate to the substrate holding stage;
a refrigerator provided inside the vacuum vessel, the refrigerator being fixed to the substrate holding stage at a location below the substrate holding stage that is different from that of the substrate mounting unit, and directly cooling the substrate holding stage;
a coolant gas inlet path including a coolant gas inlet opening that is provided at the substrate holding stage directly cooled by the refrigerator and opens to a recessed face of the recess, the coolant gas inlet path connecting a space in the recess via the coolant gas inlet opening to a coolant gas supply; and
a coolant gas outlet path including a coolant gas outlet opening that is provided at the substrate holding stage independently of the coolant gas inlet opening and opens to the recessed face of the recess, the coolant gas outlet path connecting the space in the recess via the coolant gas outlet opening to an exhaust device.

2. The substrate cooling device according to claim 1, wherein the coolant gas inlet opening and the coolant gas outlet opening open to a bottom face of the recess.

3. The substrate cooling device according to claim 1, wherein the holding member is made of a material whose heat conductivity is lower than the heat conductivity of the substrate holding stage.

4. The substrate cooling device according to claim 1, wherein, the substrate holding stage includes:
a base having a recess and a substrate holding face formed by a protrusion surrounding the recess, the base including a groove at a bottom face of the recess, the groove constituting the coolant gas inlet path or the coolant gas outlet path; and
a sealing plate fitted to the bottom face of the recess of the base, the sealing plate including the coolant gas inlet opening or the coolant gas outlet opening communicating with the groove of the base.

5. The substrate cooling device according to claim 1, wherein a wall part defining the coolant gas outlet opening includes an attachment structure that makes it possible to attach a conductance control member to an inside of the wall part, the conductance control member being for reducing an opening diameter of the coolant gas outlet opening.

6. A sputtering apparatus, comprising:
a vacuum vessel;
a substrate holding stage provided in the vacuum vessel and including a recess defining a space between a substrate mounting unit on which a substrate can be mounted and a substrate mounted on the substrate mounting unit;
a holding member provided inside the vacuum vessel, the holding member exerting a pressing force against the substrate holding stage so as to fix the substrate to the substrate holding stage;
a refrigerator provided inside the vacuum vessel, the refrigerator being fixed to the substrate holding stage at a location below the substrate holding stage that is different from that of the substrate mounting unit, and directly cooling the substrate holding stage;
a coolant gas inlet path including a coolant gas inlet opening that is provided at the substrate holding stage directly cooled by the refrigerator and opens to a recessed face of the recess, the coolant gas inlet path connecting a space in the recess via the coolant gas inlet opening to a coolant gas supply; and
a coolant gas outlet path including a coolant gas outlet opening that is provided at the substrate holding stage independently of the coolant gas inlet opening and opens to the recessed face of the recess, the coolant gas outlet path connecting the space in the recess via the coolant gas outlet opening to an exhaust device.

7. The sputtering apparatus according to claim 6, wherein the coolant gas outlet path is configured to allow the exhaust device performing exhaustion of the vacuum vessel to communicate with a space in the recess.

8. A method for manufacturing an electronic device, the method comprising forming a film on a substrate using a sputtering apparatus according to claim 6.

9. The substrate cooling device according to claim 1, wherein the refrigerator uses a stirling cycle.

10. The sputtering apparatus according to claim 6, wherein the refrigerator uses a stirling cycle.
